(19) United States
(12) Patent Application Publication
(10) Pub. No.: US 2012/0153969 A1
(43) Pub. Date: Jun. 21, 2012

(54) Measuring device working with microwave

(75) Inventors: Manfred Eckert, Todtnau (DE); Winfried Mayer, Buch (DE); Rolf Schwald, Schopfheim (DE)

(73) Assignee: Endress + Hauser GmbH + Co. KG, Maulburg (DE)

(21) Appl. No.: 13/325,925

(22) Filed: Dec. 14, 2011

(30) Foreign Application Priority Data
Dec. 15, 2010 (DE) 10 2010 063 167.1

(51) Int. Cl. G01R 27/04

(52) U.S. Cl. 324/637

(57) ABSTRACT

A measuring device working with high frequency microwaves, especially frequencies above 70 GHz, comprises a microwave module for the production of microwave transmission signals and/or for the reception and processing of received microwave signals, and an antenna unit for the transmission of the microwave transmission signals and/or for the receipt of the received microwave signals. The measuring device has a cost effective, flexibly usable connection between the microwave module and the antenna unit suitable for the transmission of high frequency microwave signals, especially frequencies of 70 GHz and more. The microwave module and the antenna unit are connected to one another via a dielectric waveguide, via which a transmission of the microwave transmission signals from the microwave module to the antenna unit and/or a transmission of the received microwave signals from the antenna unit to the microwave module occurs.

The invention relates to a measuring device that works with high frequency microwaves, especially frequencies above 70 GHz, comprising a microwave module to produce microwave transmission signals and/or to receive and process received microwave signals, an antenna unit to send the microwave transmission signals and/or to receive the received microwave signals; wherein microwave transmission signals are transmitted to the antenna unit from the microwave module and/or received microwave signals are transmitted to the microwave module from the antenna unit.

Measuring devices working with microwaves are applied, for example, in measuring and control technology, as well as in the context of industrial process automation, for measuring fill levels of a fill substance located in a container using the travel time principle. In such case, the fill level measuring device sends microwave transmission signals in the direction of the surface of the fill substance by means of a transmitting unit directed toward the fill substance, receives those reflection signals reflected by the surface of the fill substance by means of a correspondingly directed receiving unit after a travel time dependent on the fill level to be measured, and determines the fill level based on the measured travel time, the position of the transmitting and receiving unit relative to the container, and the propagation velocity of the microwave signals.

All known methods can be applied, which enable the measurement of relatively short distances by means of reflected microwave signals for determining the travel times. Examples of the most well known methods are the use of pulse radar and frequency modulation continuous wave radar (FMCW radar).

Short microwaves transmission pulses, which are reflected by the surface of the fill substance and received after a travel time, which is dependent on distance, are periodically sent in the pulse radar method. An echo function, which reflects the received signal amplitude as a function of time, is derived based on the received signal. Each value of this echo function corresponds to the amplitude of an echo reflected at a specific distance from the antenna.

A microwave signal, which is periodically linearly frequency modulated, for example, as a saw tooth function, is sent continuously in the FMCW method. Consequently, the frequency of the received echo signal has a frequency difference compared to the instantaneous frequency of the transmission signal at the point in time of the reception; the frequency difference depends on the travel time of the microwave signal and its echo signal. The frequency difference between the transmission signal and the received signal obtained through mixing both signals and evaluating the Fourier spectrum of the mixed signal corresponds to the distance from the reflecting area to the antenna. Additionally, the amplitudes of the spectral lines of the frequency spectrum obtained through the Fourier transformation correspond to the echo amplitudes. Consequently, this Fourier spectrum represents the echo function in this case.

At least one wanted echo is determined from the echo function; the wanted echo corresponds to the reflection of the transmission signal on the surface of the fill substance. With a known propagation velocity of the microwaves, the distance, over which the microwaves traveled on their path from the measuring device to the surface of the fill substance and back, directly results from the travel time of the wanted echo. The fill level sought can be directly calculated based on the installed height of the fill level measuring device over the container.

Measuring devices working with microwaves of the type named above are preferably embodied as two separate modules connected to one another, one of which comprises the microwave module and, in given cases, other electronics, especially measuring electronics, signal processing electronics, communication and/or energy supply electronics, and the other comprises the antenna unit and also, as a rule, a securement apparatus for the mechanical securement of the antenna unit at the measuring location and/or an isolation between the measuring location and the environment customized for the conditions at the measuring location. In fill level measuring technology, the latter regularly comprises corresponding container seals as well as feedthroughs provided in given cases in the antenna unit.

A large number of variants of measuring devices can be offered through the pairwise combination of different modules in a cost effective and flexible manner, without requiring an immense inventory. Thus different microwave modules and/or electronics modules can be combined with a large number of modules differing as regards isolation, securement apparatus and/or the antenna type of the antenna unit.

In connecting the respectively selected modules for the desired measuring device variants, the microwave module must be connected to the antenna unit while overcoming each provided separation between the measuring location and the environment.

This connection is currently made with coaxial cables, which are connected terminally to the microwave module and the antenna unit via corresponding plug connections. Coaxial cables are optimally suitable for this purpose based on their simple mechanical mounting via plug connections, their mechanical flexibility and their flexible length adaptable to the conditions of the location of use. They are poor heat conductors, which especially in applications in which high temperatures, which the microwave module and other electronics, in given cases, would not withstand, offers a safe protection from overheating for these components at the measuring location. Moreover, the plugged connection for the microwave module for suppressing equalizing flows between the microwave module and the antenna unit can be provided with a galvanic isolation of the inner conductor and outer conductor, and the plugged connection to the antenna unit can be equipped with a feedthrough, preferably a hermetically sealed feedthrough, for improving the isolation of the measuring location from the environment.

The range of application, in which coaxial cable can be applied for the transmission of microwave signals, is limited in regard to the frequency of these signals, however. Thus, for example, the diameter of the coaxial cable must be reduced proportionally to the reciprocal value of the frequency to assure a unimodal waveguide. If one would permit the propagation of higher modes in the coaxial cable, this would lead to a mode dispersion and a time divergence of the microwave signals, which, especially with the fill level measurement based on a travel time measurement described above, leads to noticeable measurement errors and in the extreme case would make a meaningful travel time measurement impossible.

Since the reduction of the diameter increases with rising frequency, however, the precision requirements of the coaxial cables, the plug connections and the line transitions following thereto increase in such a manner that an economic solution is not foreseeable in the next few years.

A further problem is that the attenuation in coaxial cables increases with the frequency and decreasing line cross section. Even qualitatively very high quality and therefore expensive coaxial cables have an attenuation in the order of magnitude of 3 dB in the case of a frequency of 75 GHz and a line length of 20 cm without the plug connections and the adjoining transition elements. With plug connections and transition elements, the attenuation can be up to 10 dB, even with very high value components. In the fill level measuring devices described above, this would lead to a drastic reduction of the range.

Hollow conductors with a round or rectangular cross section are an alternative to coaxial lines in the case of high frequencies, especially in the case of frequencies of 75 GHz and greater. However, these have the disadvantage that they are not flexible and, consequently, cannot be bent or twisted in order to be optimally applied and connected in the measuring device. There are, indeed, special solutions of flexible hollow conductors; however, these are extremely expensive, just as in the case of coaxial lines usable in these frequencies.

Moreover, hollow conductors with a round cross section have the problem that the polarization direction of the microwave signals is lost in the curves. Hollow conductor connections with a round cross section can consequently only be applied in connection with circularly polarized microwave signals.

The problems mentioned above can naturally be avoided when the antenna unit and microwave module are embodied as a one piece compact unit. An example for this is described in WO 2008/114043. There a patch antenna fed via a microstrip line is integrated in a microwave module; a dielectric rod protruding out from the housing of the microwave module is applied to the patch antenna; via the dielectric rod the microwave signals are transmitted out through the housing wall, or external microwave signals impinging on the antenna are transmitted into the interior of the housing. Modularity is lost in this way, however.

It is an object of the invention to provide a measuring device working with microwaves and having a microwave module and an antenna unit separated therefrom; wherein the measuring device has a cost effective, flexibly usable connection suitable for the transmission of high frequency microwave signals, especially with frequencies of 70 GHz and higher, between the microwave module and the antenna unit.

For this, the invention is a measuring device that uses high frequency microwaves, especially with frequencies greater than 70 GHz, comprising:
A microwave module for producing microwave transmission signals and/or for receiving and processing the received microwave signals,
an antenna unit for sending the microwave transmission signals and/or for receiving the received microwave signals, wherein
   the microwave module and the antenna unit of the invention are connected to one another via a dielectric waveguide, via which a transmission of the microwave transmission signals from the microwave module to the antenna unit and/or a transmission of the received microwave signals from the antenna unit to the microwave module occurs.

In an embodiment of the invention, the dielectric waveguide comprises a ceramic or a flexible synthetic material, especially polytetrafluoroethylene (PTFE).

In an additional embodiment, a plug connection terminal, in which the waveguide can be terminally inserted, is provided in the microwave module and/or in the antenna unit.

In a further development of the invention, the plug connection terminals have a funnel shaped opening, which opens into a hollow conductor; the respective end of the waveguide is introducible to the hollow conductor through the funnel shaped opening.

In an embodiment of the further development, the hollow conductor of the plug connection terminal of the antenna unit is connected to an antenna in the antenna unit.

In an additional embodiment, the dielectric waveguide is coaxially surrounded by a hollow space or a spacer; field fractions protruding outwards from the waveguide in the case of transmission of the microwave transmission signal and/or of the microwave received signal are capable of propagation in the hollow space or spacer.

In an additional further development
the microwave module has a housing comprising two half shells,
a microwave circuit is arranged in the housing, and
the inner surfaces of the half shells are electrically conductive.

In an additional further development the funnel-shaped opening and the hollow conductor of the plug connection terminal of the microwave module are formed by cavities in the half shells.

In a first variant of the invention
the microwave circuit is arranged on a board;
a microwave component with a hollow conductor connector is arranged on the board; and
the hollow conductor of the plug connection terminal of the microwave module is connected to the hollow conductor connector of the microwave component via a bore coated with a conductor in the board.

In a second variant of the invention the hollow conductor of the plug connection terminal of the microwave module in the microwave module is connected to a planar waveguide via a waveguide transition; the planar waveguide is connected to a connection of a microwave component.

In an additional further development cavities are provided in at least one of the half shells;
the cavities form a hollow conductor network closed off by an electrically conductively coated surface of the board, or
the cavities form a hollow conductor network arranged completely within the respective half shell.

In an additional further development, at least one partition, especially a wall isolating the two cavities of a half shell from one another, is provided in the inner space of the microwave module; the partition shields circuit parts arranged in the inner space of the microwave circuit from to one another.

The invention offers the advantage that a cost effective, flexibly usable connection between the microwave module and the antenna unit is formed by the dielectric waveguide; the connection is suitable for the transmission of microwave signals with high frequencies, especially frequencies of 70 GHz and higher.

Via the plug connection terminals for the waveguide, a modular construction of the measuring device is possible, in which a connection suitable for the signal transmission of high frequency microwave signals between a measuring module containing the microwave module and a sensor module containing the antenna unit can be manually produced in a simple and flexible manner.

The invention and its advantages will now be explained in greater detail based on the figures of the drawing, in which an example of an embodiment is presented; equal parts are provided with equal reference characters in the figures. The figures of the drawing show as follows:

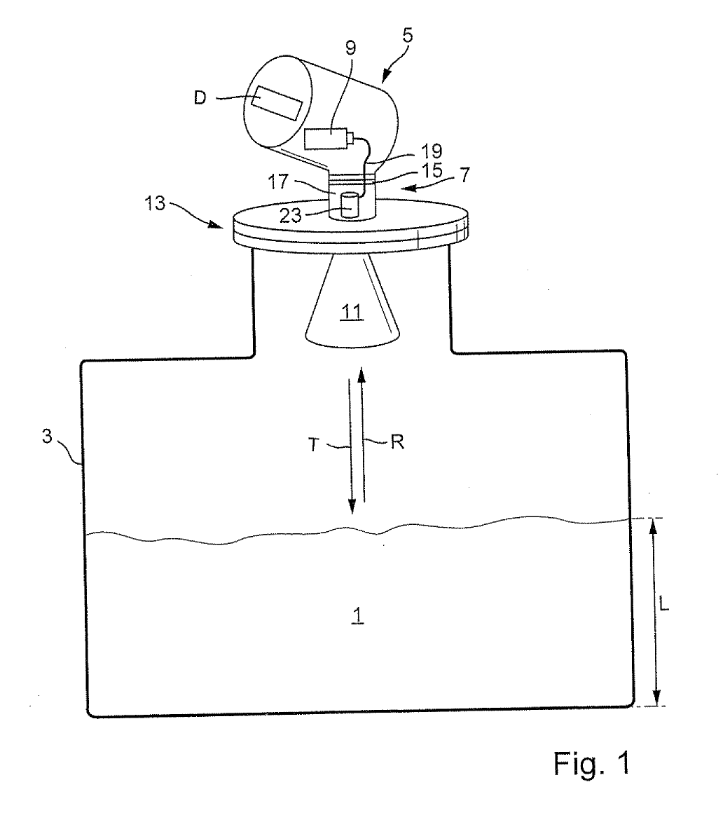

FIG. 1 a sketch of the principles of a measuring device of the invention in an example of an arrangement for fill level measurement;

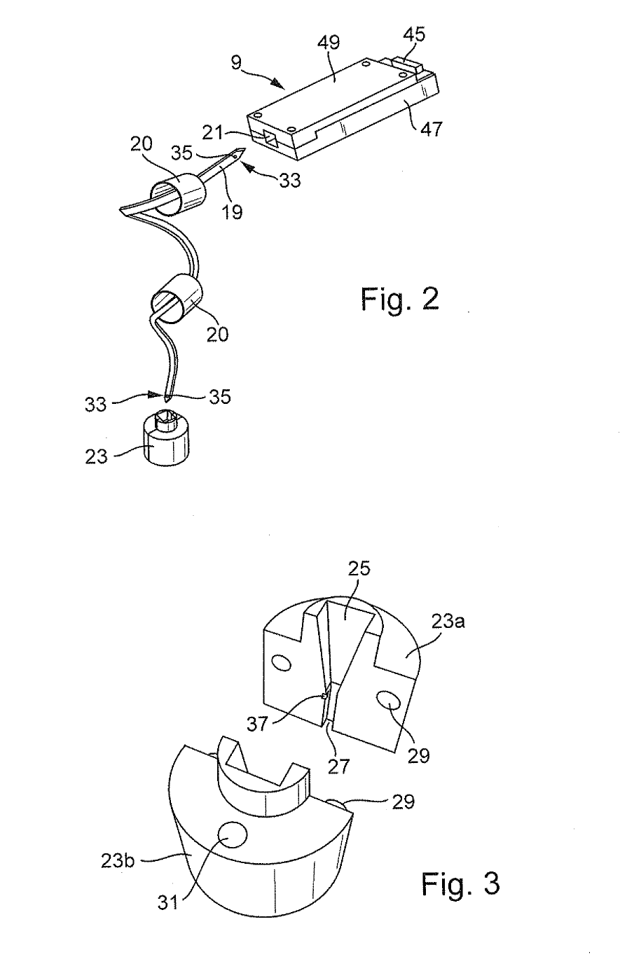

FIG. 2 an exploded view of the microwave module, the dielectric waveguide and the plug connection terminal of the sensor module in FIG. 1;

FIG. 3 the plug connection terminal of the sensor module;

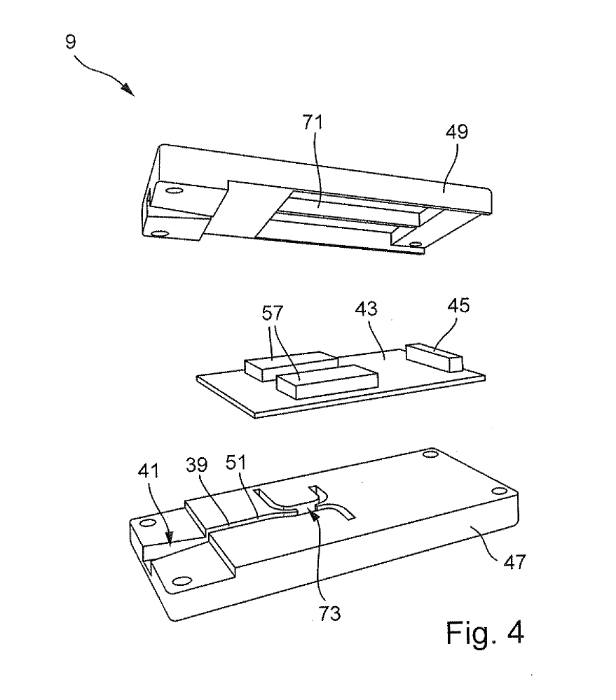

FIG. 4 an exploded view of the microwave module;

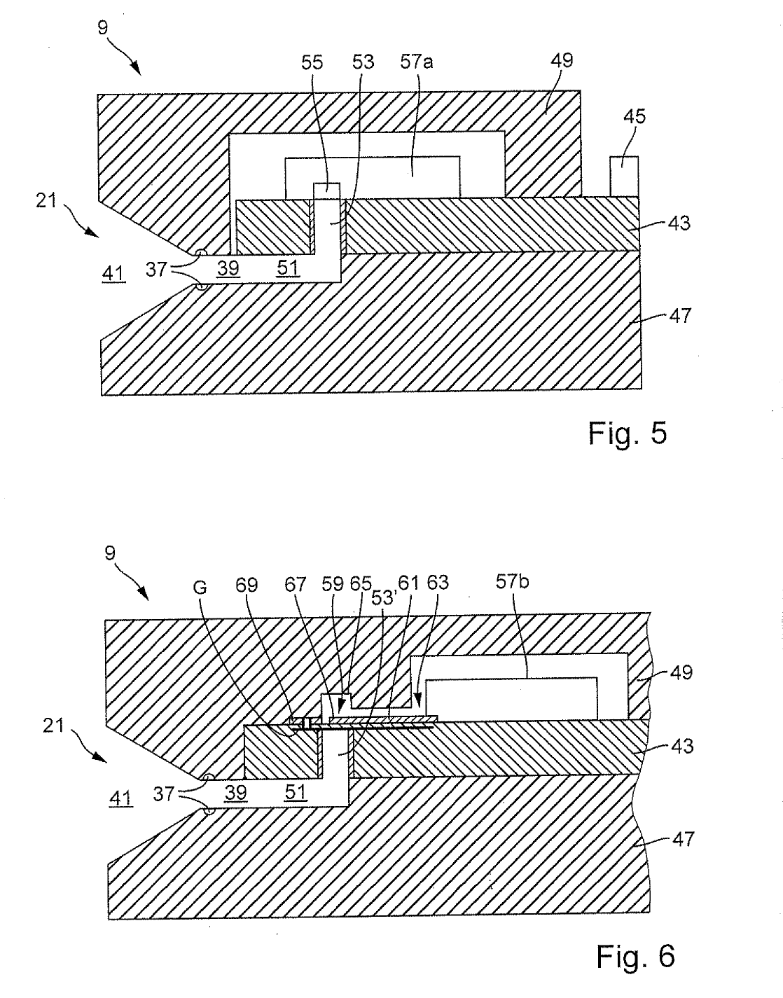

FIG. 5 a microwave module with an integrated plug connection terminal, which is connected to a hollow conductor connector of a microwave component via a hollow conductor connection; and

FIG. 6 a microwave module with an integrated plug connection terminal, which is connected to a planar waveguide via a waveguide transition.

FIG. 1 shows a sketch of the principles of a measuring device of the invention that uses microwaves. In the illustrated example, the measuring device is a fill level measuring device using the travel time principle for measuring a fill level L of a fill substance 1 in a container 3. The fill level measuring device is, for example, a pulse radar or FMCW radar fill level measuring device mentioned earlier.

According to the invention, the measuring device has a modular construction comprising a first module 5—subsequently referred to as a measuring module—and a second module 7—subsequently referred to as sensor module—connected to the first module.

The measuring module 5 has a microwave module 9 for producing microwave transmission signals T to be transmitted by the measuring device and/or for receiving and processing received microwave signals R received by the measuring device. Moreover, measuring module 5 can comprise other components, especially other electronics, especially measuring electronics, signal processing electronics, communication electronics and/or energy supply electronics, as well as, in given cases, an onsite display D.

The sensor module 7 has an antenna unit 11 with an antenna for sending the transmitted microwave signals T and/or for receiving the received microwave signals R. As presented here, for example, a horn antenna can be applied as the antenna. In such case, both round as well as rectangular shaped horn antennas with an increasing funnel cross section toward the fill substance 1 are applicable. Alternatively, dielectric rod antennas, microstrip line antennas, lens antennas or other antenna types known from the state of the art can be applied.

Moreover, sensor module 7 has a securement apparatus 13 for the mechanical securement of antenna unit 11 at the measuring location. For this, all known securement apparatuses, which effect a sufficient sealing between the measuring location and the environment for the particular application of the measuring device, can be applied. In FIG. 1 a flange, which is mounted on a counter flange provided on a container connection piece, is shown as a possible form of embodiment.

In the illustrated example of an embodiment, antenna unit 11 serves to transmit microwave transmission signals T generated by microwave module 9 toward fill substance 1 and/or to receive its reflection signal, which is reflected by the surface of the fill substance, as a microwave received signal R after a travel time dependent on the fill level L.

For fill level measurement, the received microwave signals R are fed to measuring module 5, which ascertains the travel time of the signal required for the path from the fill level measuring device to the surface of the fill substance and back, which is dependent on the fill level L, based on these signals and determines the fill level L based on this signal travel time.

The invention is subsequently described based on an antenna unit 11, which both transmits the microwave transmission signals T generated by the microwave module 9 as well as receives their reflection signals reflected by the surface of the fill substance as received microwave signals R and forwards these received microwave signals R to measuring module 5. Alternatively, the transmission can occur via one or more purely transmitting antenna units and the reception can occur via one or more purely receiving antenna units. The invention is also completely analogously applicable in connection with purely transmission antenna units, or purely reception antenna units.

Measurement module 5 and sensor module 7 are directly connected to one another, for example, by means of a mechanical connection 15. Conventional connections, such as e.g. screw or flange connections, which effect a seal against the environment, are suited as a mechanical connection 15; a through going connection between the internal spaces of measurement module 5 and sensor module 7 is provided by the inner space of mechanical connection 15. For this, for example, a connection piece 17 formed on the sensor module 7 can be provided; measuring module 5 is mounted on connection piece 17 in such a manner that an opening of the measuring module housing opens into connection piece 17.

According to the invention, microwave module 9 in the interior of measuring module 5 and antenna unit 11 of the sensor module 7 are connected to one another via a dielectric waveguide 19, via which a transmission of the microwave transmission signals T from microwave module 9 to antenna unit 11 and a transmission of the received microwave signals R from the antenna unit 11 to the microwave module 9 occur.

For this, the dielectric waveguide 19 extends through the inner space of connection 15 in the illustrated example of an embodiment.

The mechanical connection 15 between measuring module 5 and sensor 7 is not absolutely required, however. Alternatively, measuring module 5 and sensor module 7 can be arranged isolated from one another and mechanically secured, and be connected to one another via a dielectric waveguide 19, which leads from antenna unit 11 to microwave module 9 in a protective tube, preferably a flexible protective tube.

The dielectric waveguide 19 preferably comprises a flexible dielectric synthetic material, especially a thermoplastic or a ceramic. Preferably, materials with low dielectric constant, especially with a dielectric constant between 2 and 4, are applied; a low dielectric loss occurs with these materials. The dielectric waveguide 19 can be, for example, an injection molded part of polytetrafluoroethylene (PTFE). The application of a flexible material facilitates the handling of waveguide 19 during its installation and connection.

The dielectric waveguide 19 is preferably embodied as a helical shaped spring. This shape effects a high degree of flexibility as regards the length of the connection that can be realized by the waveguide 19. The latter is especially advantageous, when in different combinations of different variants of measurement modules and sensor modules, differently large distances between microwave module 9 and antenna unit 11 must be bridged by the waveguide 19. Moreover, it offers the advantage that measuring module 5 can be rotatably placed on the sensor module 7 compared to the sensor module 7. In such case, a certain excess length of waveguide 19 is available from the helical spring shape; this excess length is available for the rotation. This permits the user, for example, to orient a display A integrated in measuring module 5 in a direction desired by the user.

The dielectric waveguide 19 is coaxially surrounded by a hollow space or a spacer over its entire length extending between microwave module 9 and antenna unit 11; field fractions protruding outwards from the waveguide 19 are capable of propagation in the hollow space or spacer. In the case of the high frequencies of 70 GHz and more, the field fractions protruding out from waveguide 19 are spatially narrowly limited to the immediate environment of waveguide 19. Correspondingly a hollow space coaxially surrounding waveguide 19 and sufficiently larger than waveguide 19 is provided for the unhindered spreading of the field fractions, when the inner walls of mechanical connection 15 or of the protective tube have a minimum separation from the waveguide 19; the minimum separation is predetermined by the signal frequencies to be transmitted and the dimensions of the waveguide 19 matched thereto. The minimum separation for waveguide 19 with a rectangular cross section, for example, is on the order of magnitude of two to four times the width of the waveguide. For example, the waveguide width for the transmission of signals with frequencies above 70 GHz lies in the region of two to three millimeters. Correspondingly, a minimum separation is on the order of magnitude of 10 mm.

Moreover, the minimum separation from the inner walls of connection 15 or of the protective tube—as shown in FIG. 2—can be secured by spacers 20 comprising a material, through which an unhindered spreading of the field fractions is possible. Sleeves coaxially surrounding waveguide 19 are especially suited for this; the sleeves are pushed on waveguide 19. The spacers 20 can comprise polystyrene or polyethylene foam materials, for example. In order to obtain a high degree of flexibility of waveguide 19, a number of spacers 20 can be arranged one after the other and distributed over the length of waveguide 19; each spacer 20 coaxially surrounds only a short segment of waveguide 19. Alternatively, a single spacer, which extends over the entire length of waveguide 19, can be applied for a waveguide 19 that extends relatively straight.

The dielectric waveguide 19 offers the advantage that it effects a galvanic isolation between microwave module 9 and antenna unit 11 due to its dielectricity.

At the same time, the dielectric waveguide 19 acts as a high pass filter as regards the signal transmission. This offers the advantage that it suppresses a transmission of low frequency disturbance signals, which are produced, for example, by frequency multipliers in the microwave module 9.

The connection of the waveguide 19 to microwave module 9 and antenna unit 11 preferably occurs via a plug connection terminal 21 provided in measuring module 5 opening into microwave module 9 and a plug connection terminal 23 provided in sensor module 7 opening into antenna unit 11; the ends 33 of the waveguide 19 are terminally insertable into plug connection terminals 21, 23. FIG. 2 shows an exploded view of the microwave module 9, the waveguide 19 and the plug connection terminal 23 preferably arranged on the connection piece 17 of the sensor module 7 and opening into antenna unit 11.

The plug connection terminals 21, 23 have a preferably funnel shaped opening, which opens into a hollow conductor; each particular end 33 of waveguide 19 is inserted into its associated opening.

FIG. 3 shows an example of an embodiment of plug connection terminal 23 provided in sensor module 7. Plug connection terminal 23 comprises two halves 23a, 23b connected to one another, forming an essentially cylindrical element. Both halves 23a, 23b are each provided with cavities lying opposite one another; the cavities together form a funnel shaped opening 25 of plug connection terminal 23 and a hollow conductor 27 opening into the side of plug connection terminal lying opposite opening 25 adjacent thereto. Halves 23a, 23b as a whole, for example, comprise a conductive material such as e.g. aluminum, or they comprise a non conductive or slightly conductive material, which is provided with a conductive coating at least on the inner surfaces of halves 23a, 23b. Both halves 23a, 23b are mechanically connected to one another via a connection 29, such as e.g. a plug or screw connection. The plug connection terminal 23 is preferably directly mounted on a hollow conductor connector (not shown here) of antenna unit 11. For this, the plug connection terminal 23 is preferably superimposed directly on the hollow conductor connector, which preferably opens into in connection piece 17. For example, this hollow conductor connector can be a direct connection to a hollow conductor, which leads to the antenna of antenna unit 11. Alternatively, the hollow conductor connector can be directly connected to the antenna unit or be connected via an additional hollow conductor to a transition element, through which a transition to a planar waveguide, e.g. a microstrip line, occurs, which is then, in turn, connected to a planar antenna, e.g. a patch antenna.

Preferably, the signal transmission of the microwave transmission signals T and received microwave signals R occurs in antenna unit 11 via a feedthrough, such as e.g. a glass feedthrough applied in one of the hollow conductors in antenna unit 11; the glass feedthrough preferably effects a pressure resistant and gas tight isolation against the measuring location, here the interior of the container.

The securement of plug connection terminal 23 occurs, for example, via securement screws leading externally of opening and hollow conductor 27 axially through bores 31, which lead through plug connection terminal 23.

In connection with waveguide 19, which has a rectangular cross section, illustrated in FIG. 2, funnel shaped opening 25 has rectangular cross section tapering toward hollow conductor 27 and hollow conductor 27 correspondingly has a rectangular cross section. Rectangular cross sections are preferably used for the transmission of linearly polarized microwave signals. Alternatively, for the transmission of circularly polarized microwave signals, traversing circular cross sections can naturally also be applied, i.e. for the waveguide, the funnel shaped opening and the hollow conductor.

In both variants, the cross section funnel shaped opening 25 toward hollow conductor 27 can continuously taper, as presented here or, however, can also decrease in a stepped manner to the cross section of the hollow conductor 27.

Waveguide 19 is connected by having its end introduced or pressed into the funnel shaped opening 25. For this, waveguide 19 preferably has tapering ends 33. Preferably, an engagement apparatus is provided, through which the end of waveguide 19 engages in a fixed position in opening 25. The engagement apparatus comprises, for example, at least one detent 35 provided terminally externally on the broad side of waveguide 19. This can be formed by a cylindrical or hemispherical protrusion, for example. Identical cavities 37, into which detents 35 engage, are provided to accommodate detent 35 or detents 35 in plug connection terminal 23, for example, in the region of the transition between opening 25 and hollow conductor 27.

Plug connection terminal 21 opening into microwave module 9 likewise has a funnel shaped in a hollow conductor 39 opening into opening 41, and is preferably integrated in microwave module 9. FIG. 4 shows an example of an embodiment for this. Microwave module 9 comprises a board 43 on which a microwave circuit, which is not shown in detail here, is arranged as well as, in given cases, a connector apparatus 45, via, which other electronics can be connected to microwave module 9.

The board 43 is surrounded by a housing, which preferably comprises two half shells 47, 49, which are connected to one another and enclose board 43; the inner surfaces of half shells 47, 49 are conductive. For this, half shells 47, 49 can, as a whole, comprise a conductive material such as e.g. aluminum. Alternatively, non conductive or slightly conductive materials can also be applied, which are at least provided with a conductive coating on the inner surfaces. Thus, for example, metalized, injection molded plastic parts can be applied as half shells 47, 49

The two half shells 47, 49 of microwave module 5 effect a mechanical protection and an electrical shielding of the microwave circuit against the environment.

Moreover, they can undertake other functions, which are described in greater detail based on examples below, through a corresponding formation of separate hollow spaces between half shells 47, 49 and board 43 enclosed by inwardly opening into conductive side surfaces.

Exactly as with plug connection terminal 23, both half shells 47, 49 have cavities on the input side lying opposite one another; the cavities together form the funnel shaped opening 41 of plug connection terminal 21, which passes through hollow conductor 39 to microwave module 5. The hollow conductor 39 is preferably formed by a corresponding cavity in only one of the two half shells—here the lower half shell 47. The connection of waveguide 19 also occurs here, in that the end 33 of waveguide 19 is inserted through opening 41 and pressed in there or is affixed to a fixed position by an engagement apparatus identical to the engagement apparatus previously described.

Hollow conductor 39 is connected to the microwave circuit in the interior of microwave module 9. For this, the hollow conductor 37 can be connected, for example,—as shown in FIG. 5—to a hollow conductor connector 55 of a microwave component 57a located directly thereacross or via an additional hollow conductor 51 formed by a corresponding cavity in the lower half shell 47 via a conductively coated bore 53 leading through board 43 to form a hollow conductor. Microwave components with hollow conductor connector are described, for example, in the article ‘Millimeter Wave SMT Low Cost Plastic Packages for Automotive RADAR at 77 GHz and High Date rate E-band Radios’ by P F. Alléaume, C. Toussain, T. Huet, M. Camiade of United Monolithic Semiconductors, Orsay, 91401 France, published in 2009 in the Microwave Symposium Digest of the IEEE on pages 789 to 792.

Alternatively,—as shown in FIG. 6—a waveguide transition can be provided in microwave module 9; via which hollow conductor 39 of plug connection terminal 21 in the microwave module 9 is connected to a planar waveguide 61. Planar waveguide 61 is, for example, a microstrip line or a coplanar line, which is applied on board 43, and is terminally connected to a microwave component 57b equipped with a connection 63 designed for planar waveguides. As presented here, for example, the waveguide transition 59 is arranged on the upper side of board 43, and is connected to hollow conductor 39 of plug connection terminal 21 via a conductively coated bore 53′, which leads through board 43 to the upper side of the circuit board and forms a hollow conductor, either directly or via an additional hollow conductor 51 formed by the corresponding cavity in the lower half shell 47. The waveguide transition 59 comprises a hollow conductor termination 65, which seals the hollow conductor formed by the bore 53′ on its side lying opposite the hollow conductor 39 of the plug connection terminal 21, and a projection 67 formed on the end of planar waveguide 61; projection 67 protrudes into in the hollow space surrounded by the hollow conductor termination 65 and the bore 57′. Projection 67 lies over bore 53′ on a thin dielectric covering bore 53′ on an upper layer of board 47. For example, the projection 67 is a planar structure with a trapezoidal shaped base and lies in a direction perpendicular to the longitudinal axis of bore 53′.

The hollow conductor termination 65 forms an electrically conductive cap covering bore 53′; the cap is in electrically conductive contact to the conductive coating of bore 53′. The cap is electrically insulated from waveguide 61 and its projection 67, e.g. via a corresponding separation. For example, the hollow conductor termination 65—as here presented—can be formed by a correspondingly formed cavity in upper half shell 49. In such case, the electrical contact to the coating of bore 53′ occurs via an electrically conductive end face of half shell 49 surrounding on the exterior of the cavity under the cavity of the circuit board section covered by the planar waveguide 61; the electrically conductive end face of half shell 49 lies on an identically shaped contact surface 69 on the surface of board 43. Contact surface 69 is connected to a ground conductor G, which is integrated in the upper region of board 43, via electrically conducting vias distributed and arranged around the cavity; in turn, ground conductor G is in direct electrical contact with the conductive coating of bore 53′.

Where the conductive connection between the end face of half shell 49 and the coating of bore 53′, e.g. due to component tolerances of board 43, cannot be assured, an electrically conductive cap can alternatively be applied as a hollow conductor termination; the electrically conductive cap is superimposed as a single element on board 43.

As previously mentioned, half shells 47, 49 can undertake other additional functions in addition to functioning as plug connection terminal 21 and as hollow conductor termination 65 achieved through a corresponding formation of the separate hollow spaces surfaces enclosed by conductive sides pointing inward between half shells 47, 49 and board 43.

Thus, for example, partitions 71 can be provided in the inner space of microwave module 9; partitions 71 shield individual circuit parts or group of circuit parts from one another. This is presented in FIG. 4 using the example of two microwave components 57 applied on board 43. Partition 71 is arranged here in upper half shell 49 between two hollow spaces formed by cavities in upper half shell 49; each hollow space surrounds one microwave component 57. Preferably, an end face of partition 71 lies on a region of board 43, on which a structure continuing the shielding is provided.

Additionally, half shells 47, 49 can undertake or support the function of individual components of the microwave circuit through the formation of their internal spaces—as previously shown using the example of hollow conductor termination 65.

Moreover, simple hollow conductor networks 73, such as e.g. a filter or coupler, can be constructed via the formation of the cavities in half shells 47, 49 themselves or in connection with conductively coated regions of the surface of board 43 adjoining thereto. FIG. 4 shows a view of a hollow conductor network 73 in lower half shell 47, which is closed from above by the metalized underside of boards 43 lying thereon. In such case, the electrical conductive surfaces of the structure in the half shell, together with the electrically conductive circuit board coating provided to cover the structure at least in this region, form the walls of the hollow conductor structure. For this, a good conductive connection between the surfaces of the circuit board coating and half shell 47 adjoining one another and used as a hollow conductor bounding wall is required.

Where such a conductive connection, e.g. due to component tolerances of board 43 cannot be assured, the hollow conductor networks 73 can also be arranged within the respective half shell 47, 49. For this, the particular half shell, for example, can comprise two layers connected to one another, in which each required structure can be machined in the form of cavities.

If needed, in addition to or instead of the single connection to a single microwave component 57 arranged on board 43 guided through board 43 previously described, other connections, which are embodied in this way with a hollow conductor connector or with a planar connection, to other microwave components can naturally be provided. Thereby e.g. hollow conductor networks having a number of outputs or inputs can be connected to microwave components located thereabove.

The two half-shells 47, 49 are pressed to one another by rivets or screws, for example. For the equalization of thickness tolerances of board 43 arising in given cases, especially in the case of application of multi-ply boards 43, a gap surrounding the exterior of board 43 for accommodating a conductive seal or a conductive adhesive is provided between the two half shells 47, 49.

The invention is not limited to fill level measuring devices, but, instead can be applied in other measuring devices, in which high frequency microwave signals are transmitted between a microwave module serving as a transmitter and/or as a receiver and an antenna unit. An example for this is a separation meter, as used in the automobile industry, for example.
1 fill substance
3 container
5 measurement module
7 sensor module
9 microwave module
11 antenna unit
13 securement apparatus
15 mechanical connection
17 connection piece
19 dielectric waveguide
20 spacers
21 plug connection terminal
23 plug connection terminal
23a half of a plug connection terminal
23b half of a plug connection terminal
25 funnel-shaped opening
27 hollow conductor
29 mechanical connection
31 bore
33 end of the waveguide
35 detent
37 cavity
39 hollow conductor segment
41 funnel-shaped opening
43 board
45 connector apparatus
47 half shell
49 half shell
51 hollow conductor
53 bore
53′ bore
55 hollow conductor connector
57 microwave component
57a microwave component with hollow conductor connector
57b microwave component with connection for a planar waveguide
59 waveguide transition
61 planar waveguide
63 connection for a planar waveguide
65 hollow conductor termination
67 projection
69 contact surface
71 partition
73 hollow conductor network

1-12. (canceled)

13. A measuring device working with high frequency microwaves, especially with frequencies greater than 70 GHz, comprising:
a microwave module to produce microwave transmission signals and/or receive and process received microwave signals;
an antenna unit to send the microwave transmission signals and/or to receive the received microwave signals; and
a dielectric waveguide for connecting said microwave module and said antenna unit, via which a transmission of the microwave transmission signals from said microwave module to said antenna unit and/or a transmission of the received microwave signals from said antenna unit to said microwave module occurs.

14. The measuring device working with microwaves as claimed in claim 13, wherein:
said dielectric waveguide comprises a ceramic or a flexible synthetic material, especially polytetrafluoroethylene (PTFE).

15. The measuring device working with microwaves as claimed in claim 13, further comprising:
a plug connection terminal provided in said microwave module and/or in said antenna unit; and
said dielectric waveguide is insertable terminally into said plug connection terminals.

16. The measuring device working with microwaves as claimed in claim 15, wherein:
said plug connection terminals have a funnel shaped opening into a hollow conductor; and
the respective end of said waveguide are introducible into said hollow conductor through said opening.

17. The measuring device working with microwaves as claimed in claim 13, wherein:
the hollow conductor of said plug connection terminal of said antenna unit is connected to an antenna in said antenna unit.

18. The measuring device working with microwaves as claimed in claim 13, wherein:
said dielectric waveguide is coaxially surrounded by a hollow space or a spacer, in which field fractions protruding outwards from said waveguide during a transmission of the microwave transmission signal and/or of the microwave received signal are capable of propagation.

19. The measuring device working with microwaves as claimed in claim 13, wherein:
said microwave module has a housing that comprises two half shells;
a microwave circuit is arranged in the housing; and
the inner surfaces of said half shells are electrically conductive.

20. The measuring device working with microwaves as claimed in claim 19, wherein:
said funnel shaped opening and said hollow conductor of said plug connection terminal of said microwave module are formed by cavities in said half shells.

21. The measuring device working with microwaves as claimed in claim 19, wherein:
said microwave circuit is arranged on a board;
a microwave component with a hollow conductor connector is arranged on said board; and
said hollow conductor of said plug connection terminal of said microwave module is connected to said hollow conductor connector of said microwave component via a bore coated with a conductive material in said board.

22. The measuring device working with microwaves as claimed in claim 19, wherein:
said hollow conductor of said plug connection terminal of said microwave module in said microwave module is connected via a waveguide transition to a planar waveguide, which is connected to a connection of a microwave component.

23. The measuring device working with microwaves as claimed in claim 19, wherein:
cavities are provided in at least one of said half shells,
said cavities form a hollow conductor network closed off by an electrically conductively coated surface of said board; or
said cavities form a hollow conductor network arranged completely within the respective half shell.

24. The measuring device working with microwaves as claimed in claim 19, wherein:
at least one partition, especially a partition that isolates said two cavities of one of said half shells from one another, is provided in the inner space of said microwave module; and
said partition shields circuit parts of the microwave circuit arranged in the inner space from one another.
